(19) United States
(12) Patent Application Publication
(10) Pub. No.: US 2014/0369150 A1
(43) Pub. Date: Dec. 18, 2014

(54) COLUMN DECODERS

(71) Applicant: SK hynix Inc., Icheon-si Gyeonggi-do (KR)

(72) Inventor: Tae Kyun SHIN, Icheon-si Gyeonggi-do (KR)

(21) Appl. No.: 14/084,149

(22) Filed: Nov. 19, 2013

(30) Foreign Application Priority Data
Jun. 17, 2013 (KR) 10-2013-0069278

(51) Int. Cl. G11C 8/10

(52) U.S. Cl. CPC G11C 8/10
USPC 365/230.06

(57) ABSTRACT

Column decoders are provided. The column decoder includes a power supplier and a column selection signal generator. The power supplier generates a supply voltage signal from a power voltage in response to a control signal enabled from a start point of time of a write mode or a read mode till an end point of time of a burst length. A level of the supply voltage signal is controlled according to the control signal. The column selection signal generator operates while the supply voltage signal is supplied. The column selection signal generator generates one of column selection signals, which is selectively enabled according to a logic combination of a high-order address signal, a mid-order address signal and a low-order address signal which are generated by decoding column address signals.

### CROSS-REFERENCE TO RELATED APPLICATION

The present application claims priority under 35 U.S.C. 119(a) to Korean Application No. 10-2013-0069278, filed on Jun. 17, 2013, in the Korean Intellectual Property Office, which is incorporated herein by reference in its entirety as set forth in full.

### BACKGROUND

1. Technical Field

Embodiments of the present disclosure generally relate to semiconductor devices and, more particularly, to column decodes.

2. Related Art

In general, semiconductor memory devices may decode address signals supplied from an external device to generate column selection signals in a write mode or in a read mode. That is, the semiconductor memory devices may store the input data into memory cells selected by the column selection signals in the write mode or may output the data stored in the memory cells selected by the column selection signals in the read mode.

FIG. 1 is a circuit diagram of a conventional column decoder included in semiconductor memory devices.

As illustrated in FIG. 1, the conventional column decoder includes a PMOS transistor P10, a first buffer 1 and a second buffer 2. The PMOS transistor P10 supplies a power voltage VDD in response to a power-off signal PWROFF. The first buffer 1 inversely buffers a column address signal YA<N> inputted from an external device. The second buffer 2 inversely buffers an output signal of the first buffer 1 to generate a column selection signal YI<N>. The power-off signal PWROFF is enabled to prevent the power voltage VDD from being supplied to the first and second buffers 1 and 2 in a standby power-down mode and in a self-refresh mode.

Specifically, the PMOS transistor P10 may be turned off to prevent the power voltage VDD from being transmitted to the first and second buffers 1 and 2 in the standby power-down mode and in the self-refresh mode. In contrast, the PMOS transistor P10 may be turned on to supply the power voltage VDD to the first and second buffers 1 and 2 when the semiconductor memory devices are out of the standby power-down mode and the self-refresh mode. The first buffer 1 may be an inverter including a PMOS transistor P11 and an NMOS transistor N11, and the second buffer 2 may also be an inverter including a PMOS transistor P12 and an NMOS transistor N12. Thus, when the column address signal YA<N> has a logic “high” level, the PMOS transistor P11 may be turned off and the NMOS transistor N11 may be turned on. As a result, an output node ND10 of the first buffer 1 may be driven to have a logic “low” level. In such a case, the PMOS transistor P12 may be turned on and the NMOS transistor N12 may be turned off. Thus, the column selection signal YI<N> may be generated to have a logic “high” level. FIG. 1 also illustrated ground voltage VSS.

As described above, when the power-off signal PWROFF is enabled in the standby power-down mode and in the self-refresh mode, the power voltage VDD is not supplied to the conventional column decoder. Thus, it may prevent a leakage current characteristic of the column decoder from being degraded even though the PMOS transistors P11 and P12 have a poor leakage current characteristic. However, when the NMOS transistors N11 and N12 have a poor leakage current characteristic, it may be difficult to improve the leakage current characteristic of the column decoder.

### SUMMARY

Various embodiments are directed to column decoders.

According to some embodiments, a column decoder includes a control signal generator, a power supplier and a column selection signal generator. The control signal generator generates a control signal enabled from a start point of time of a write mode or a read mode till an end point of time of a burst length. The power supplier generates a supply voltage signal from a power voltage in response to the control signal. A level of the supply voltage signal is controlled according to the control signal. The column selection signal generator operates while the supply voltage signal is supplied thereto. The column selection signal generator generates one of column selection signals, which is selectively enabled according to a logic combination of a high-order address signal, a mid-order address signal and a low-order address signal which are generated by decoding column address signals.

According to further embodiments, a column decoder includes a power supplier and a column selection signal generator. The power supplier generates a supply voltage signal from a power voltage in response to a control signal enabled from a start point of time of a write mode or a read mode till an end point of time of a burst length. A level of the supply voltage signal is controlled according to the control signal. The column selection signal generator operates while the supply voltage signal is supplied thereto. The column selection signal generator generates one of column selection signals, which is selectively enabled according to a logic combination of a high-order address signal, a mid-order address signal and a low-order address signal which are generated by decoding column address signals.

According to an embodiment, a column decoder includes a control signal generator configured to generate a control signal for a period starting from receiving a write pulse or read pulse signal and ending with a burst length signal; a power supplier configured to generate a supply voltage signal from a power voltage in response to the control signal, a level of the supply voltage signal being controlled according to the control signal; and a column selection signal generator configured to operate while the supply voltage signal is supplied thereto.

### BRIEF DESCRIPTION OF THE DRAWINGS

Embodiments of the present invention will become more apparent in view of the attached drawings and accompanying detailed description, in which:

FIG. 1 is a circuit diagram of a conventional column decoder included in semiconductor memory devices;

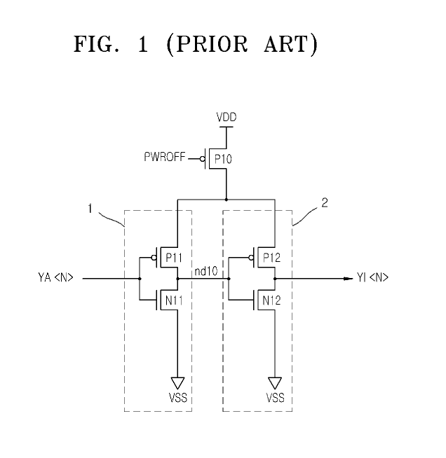

FIG. 2 is a block diagram illustrating a column decoder according to some embodiments;

FIG. 3 is a circuit diagram illustrating a power supplier included in the column decoder of FIG. 2;

FIG. 4 is a block diagram illustrating a column selection signal generator included in the column decoder of FIG. 2;

FIG. 5 is a circuit diagram illustrating a first decoder included in the column selection signal generator of FIG. 4;

FIG. 6 is a timing diagram illustrating an operation of a column decoder according to an embodiment; and

FIG. 7 is a timing diagram illustrating an operation of a column decoder according to an embodiment.

### DETAILED DESCRIPTION OF THE EMBODIMENTS

Embodiments of the present invention will be described hereinafter with reference to the accompanying drawings. However, the embodiments described herein are for illustrative purposes only and are not intended to limit the scope of the invention.

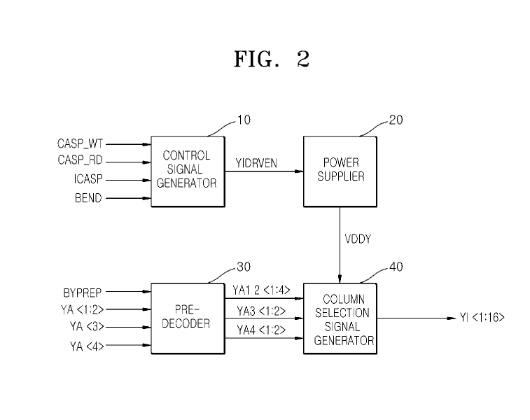

Referring to FIG. 2, a column decoder according to some embodiments may be configured to include a control signal generator 10, a power supplier 20, a pre-decoder 30 and a column selection signal generator 40.

The control signal generator 10 may generate a control signal YIDRVEN enabled from a point of time that a write pulse signal CASP_WT or a read pulse signal CASP_RD is inputted till a point of time that a burst length information signal ICASP or a burst length end signal BEND is inputted. The write pulse signal CASP_WT may be a signal including a pulse supplied from an external device in a write mode, and the read pulse signal CASP_RD may be a signal including a pulse supplied from an external device in a read mode. Further, the burst length information signal ICASP may be a signal including pulses supplied from an external device in order to set the number of bits of data which are inputted or outputted by a single write command or a single read command, and the burst length end signal BEND may be a signal including a pulse supplied from an external device at a point of time that an output of all bits of the data terminates after the write command or the read command is inputted.

The power supplier 20 may generate a supply voltage signal VDDY having a level of a power voltage VDD when the control signal YIDRVEN is enabled. Further, the power supplier 20 may generate the supply voltage signal VDDY having a predetermined level which is lower than the power voltage VDD when the control signal YIDRVEN is disabled.

The pre-decoder 30 may decode first and second high-order column address signals YA<1:2>, a mid-order column address signal YA<3>, and a low-order column address signal YA<4> in response to an input/output (I/O) control signal BYPREP to generate first to fourth high-order address signals YA12<1:4>, first and second mid-order address signals YA3<1:2>, and first and second low-order address signals YA4<1:2>. The I/O control signal BYPREP may be supplied from an external device to generate a column selection signal YI, and the column selection signal YI may be generated by decoding the column address signals YA<1:2>, YA<3> and YA<4> in the write mode or in the read mode. Further, the column address signals YA<1:2>, YA<3> and YA<4> may be generated by decoding address signals supplied from an external device.

The column selection signal generator 40 may operate when the supply voltage signal VDDY is supplied thereto and may generate one of first to sixteenth column selection signals YI<1:16>, which is selectively enabled according to a logic combination of the first to fourth high-order address signals YA12<1:4>, the first and second mid-order address signals YA3<1:2>, and the first and second low-order address signals YA4<1:2>.

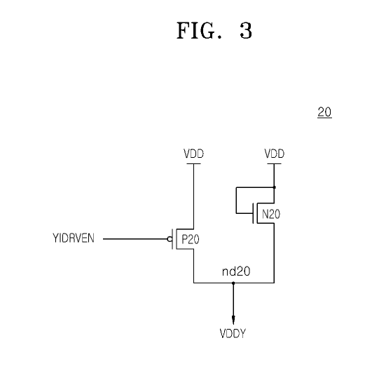

A configuration of the power supplier 20 will be described more fully hereinafter with reference to FIG. 3.

Referring to FIG. 3, the power supplier 20 may include a first drive element P20 and a second drive element N20. The first drive element P20 may be connected to a power voltage terminal VDD and a node ND20, and the second drive element N20 may also be connected to the power voltage terminal VDD and the node ND20. The first drive element P20 may drive a level of the node ND20 to the power voltage VDD to generate the supply voltage signal VDDY having a level of the power voltage VDD when the control signal YIDRVEN is enabled, and the second drive element N20 may decrease a level of the node ND20 to generate the supply voltage signal VDDY having a predetermined level which is lower than the power voltage VDD when the control signal YIDRVEN is disabled. The second drive element N20 may be realized using a diode element composed of a saturated MOS transistor having a gate electrode and a drain electrode which are electrically connected to the power voltage terminal VDD. Thus, the second drive element N20 may drive the node ND20 to have a voltage level which is lower than the power voltage VDD by a threshold voltage thereof. That is, the power supplier 20 may generate the supply voltage signal VDDY having a level of the power voltage VDD when the control signal YIDRVEN is enabled and may generate the supply voltage signal VDDY having a voltage level which is lower than the power voltage VDD by a threshold voltage of the second drive element N20 when the control signal YIDRVEN is disabled.

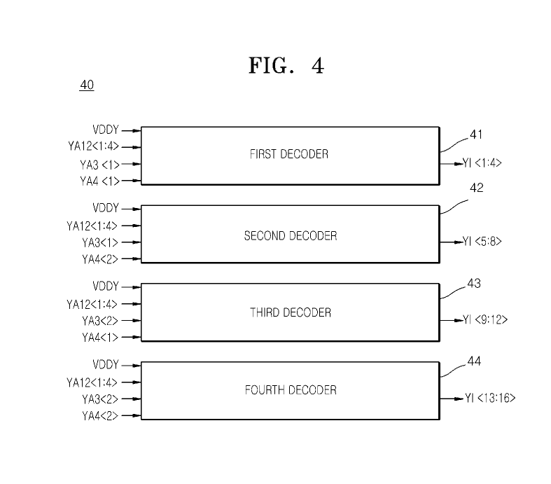

A configuration of the column selection signal generator 40 will be described more fully hereinafter with reference to FIG. 4.

Referring to FIG. 4, the column selection signal generator 40 may include a first decoder 41, a second decoder 42, a third decoder 43 and a fourth decoder 44.

The first decoder 41 may operate when the supply voltage signal VDDY is supplied thereto. While the supply voltage signal VDDY is supplied to the first decoder 41, the first decoder 41 may buffer the first to fourth high-order address signals YA12<1:4> to generate one of the first to fourth column selection signals YI<1:4>, which is selectively enabled when the first low-order address signal YA4<1> and the first mid-order address signal YA3<1> are enabled.

The second decoder 42 may operate when the supply voltage signal VDDY is supplied thereto. While the supply voltage signal VDDY is supplied to the second decoder 42, the second decoder 42 may buffer the first to fourth high-order address signals YA12<1:4> to generate one of the fifth to eighth column selection signals YI<5:8>, which is selectively enabled when the second low-order address signal YA4<2> and the first mid-order address signal YA3<1> are enabled.

The third decoder 43 may operate when the supply voltage signal VDDY is supplied thereto. While the supply voltage signal VDDY is supplied to the third decoder 43, the third decoder 43 may buffer the first to fourth high-order address signals YA12<1:4> to generate one of the ninth to twelfth column selection signals YI<9:12>, which is selectively enabled when the first low-order address signal YA4<1> and the second mid-order address signal YA3<2> are enabled.

The fourth decoder 44 may operate when the supply voltage signal VDDY is supplied thereto. While the supply voltage signal VDDY is supplied to the fourth decoder 44, the fourth decoder 44 may buffer the first to fourth high-order address signals YA12<1:4> to generate one of the thirteenth to sixteenth column selection signals YI<13:16>, which is selectively enabled when the second low-order address signal YA4<2> and the second mid-order address signal YA3<2> are enabled.

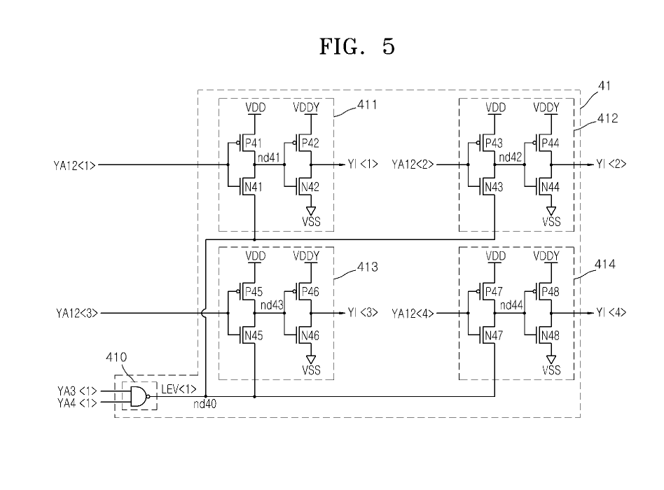

A configuration of the first decoder 41 will be described more fully hereinafter with reference to FIG. 5.

Referring to FIG. 5, the first decoder 41 may include a first logic unit 410, a first buffer 411, a second buffer 412, a third buffer 413 and a fourth buffer 414. The first logic unit 410 may drive a level of a node ND40 to generate a first level signal LEV<1> having a ground voltage VSS when the first low-order address signal YA4<1> and the first mid-order address signal YA3<1> are enabled. Alternatively, the first logic unit 410 may drive a level of the node ND40 to generate the first level signal LEV<1> having the power voltage VDD when at least one of the first low-order address signal YA4<1> and the first mid-order address signal YA3<1> is disabled. The first buffer 411 may buffer the first high-order address signal YA12<1> to generate the first column selection signal YI<1> while the supply voltage signal VDDY and the first level signal LEV<1> are supplied to the first buffer 411. The second buffer 412 may buffer the second high-order address signal YA12<2> to generate the second column selection signal YI<2> while the supply voltage signal VDDY and the first level signal LEV<1> are supplied to the second buffer 412. The third buffer 413 may buffer the third high-order address signal YA12<3> to generate the third column selection signal YI<3> while the supply voltage signal VDDY and the first level signal LEV<1> are supplied to the third buffer 413. The fourth buffer 414 may buffer the fourth high-order address signal YA12<4> to generate the fourth column selection signal YI<4> while the supply voltage signal VDDY and the first level signal LEV<1> are supplied to the fourth buffer 414. Each of the second, third and fourth decoders 42, 43 and 44 may have substantially the same configuration as the first decoder 41. Thus, detailed descriptions to the second, third and fourth decoders 42, 43 and 44 will be omitted.

In more detail, an operation of the first decoder 41 will be described with reference to FIG. 5 in conjunction with an example that the first column selection signal YI<1> among the first to fourth column selection signals YI<1:4> is selectively enabled in the write mode or the read mode and an example that all the first to fourth column selection signals YI<1:4> are disabled after the write mode or the read mode.

First, the example that the first column selection signal YI<1> among the first to fourth column selection signals YI<1:4> is selectively generated in the write mode or the read mode will be described hereinafter.

The first logic unit 410 may receive the first low-order address signal YA4<1> having a logic “high” level and the first mid-order address signal YA3<1> having a logic “high” level to generate the first level signal LEV<1> having a logic “low” level.

The first buffer 411 may be realized using first and second inverters which are cascaded. The first inverter may include a PMOS transistor P41 and an NMOS transistor N41 which are serially connected between the power voltage terminal VDD and the node ND40, and the second inverter may include a PMOS transistor P42 and an NMOS transistor N42 which are serially connected between the supply voltage signal terminal VDDY and the ground voltage terminal VSS. The PMOS transistor P41 of the first buffer 411 may be turned off in response to the first high-order address signal YA12<1> having a logic “high” level, and the NMOS transistor N41 may be turned on in response to the first high-order address signal YA12<1> having a logic “high” level to drive a level of a node ND41 (i.e., an output node of the first inverter) to the ground voltage VSS. The PMOS transistor P42 of the first buffer 411 may be turned on because the node ND41 has a logic “low” level, and the NMOS transistor N42 may be turned off to generate the first column selection signal YI<1> having a logic “high” level.

The second buffer 412 may be realized using first and second inverters which are cascaded. The first inverter of the second buffer 412 may include a PMOS transistor P43 and an NMOS transistor N43 which are serially connected between the power voltage terminal VDD and the node ND40, and the second inverter of the second buffer 412 may include a PMOS transistor P44 and an NMOS transistor N44 which are serially connected between the supply voltage signal terminal VDDY and the ground voltage terminal VSS. The PMOS transistor P43 of the second buffer 412 may be turned on in response to the second high-order address signal YA12<2> having a logic “low” level, and the NMOS transistor N43 may be turned off in response to the second high-order address signal YA12<2> having a logic “low” level to drive a level of a node ND42 (i.e., an output node of the first inverter of the second buffer 412) to the power voltage VDD. The PMOS transistor P44 of the second buffer 412 may be turned off because the node ND42 has a logic “high” level, and the NMOS transistor N44 of the second buffer 412 may be turned on to generate the second column selection signal YI<2> having a logic “low” level.

The third buffer 413 may be realized using first and second inverters which are cascaded. The first inverter of the third buffer 413 may include a PMOS transistor P45 and an NMOS transistor N45 which are serially connected between the power voltage terminal VDD and the node ND40, and the second inverter of the third buffer 413 may include a PMOS transistor P46 and an NMOS transistor N46 which are serially connected between the supply voltage signal terminal VDDY and the ground voltage terminal VSS. The PMOS transistor P45 of the third buffer 413 may be turned on in response to the third high-order address signal YA12<3> having a logic “low” level, and the NMOS transistor N45 may be turned off in response to the third high-order address signal YA12<3> having a logic “low” level to drive a level of a node ND43 (i.e., an output node of the first inverter of the third buffer 413) to the power voltage VDD. The PMOS transistor P46 of the third buffer 413 may be turned off because the node ND43 has a logic “high” level, and the NMOS transistor N46 of the third buffer 413 may be turned on to generate the third column selection signal YI<3> having a logic “low” level.

The fourth buffer 414 may be realized using first and second inverters which are cascaded. The first inverter of the fourth buffer 414 may include a PMOS transistor P47 and an NMOS transistor N47 which are serially connected between the power voltage terminal VDD and the node ND40, and the second inverter of the fourth buffer 414 may include a PMOS transistor P48 and an NMOS transistor N48 which are serially connected between the supply voltage signal terminal VDDY and the ground voltage terminal VSS. The PMOS transistor P47 of the fourth buffer 414 may be turned on in response to the fourth high-order address signal YA12<4> having a logic “low” level, and the NMOS transistor N47 may be turned off in response to the fourth high-order address signal YA12<4> having a logic “low” level to drive a level of a node ND44 (i.e., an output node of the first inverter of the fourth buffer 414) to the power voltage VDD. The PMOS transistor P48 of the fourth buffer 414 may be turned off because the node ND44 has a logic “high” level, and the NMOS transistor N48 of the fourth buffer 414 may be turned on to generate the fourth column selection signal YI<4> having a logic “low” level.

Next, the example that all the first to fourth column selection signals YI<1:4> are disabled after the write mode or the read mode will be described hereinafter.

The first logic unit 410 may receive the first low-order address signal YA4<1> having a logic “low” level and the first mid-order address signal YA3<1> having a logic “low” level to generate the first level signal LEV<1> having a logic “high” level.

The PMOS transistor P41 of the first buffer 411 may be turned on in response to the first high-order address signal YA12<1> having a logic “low” level, and the NMOS transistor N41 may be turned off in response to the first high-order address signal YA12<1> having a logic “low” level to drive a level of the node ND41 (i.e., an output node of the first inverter) to the power voltage VDD. In such a case, a leakage current path of the first inverter of the first buffer 411 may be open because the first level signal LEV<1> having a logic “high” level is applied to a source terminal of the NMOS transistor N41. The PMOS transistor P42 of the first buffer 411 may be turned off because the node ND41 is driven to a logic “high” level, and the NMOS transistor N42 may be turned on to generate the first column selection signal YI<1> having a logic “low” level. In such a case, a leakage current path of the second inverter of the first buffer 411 may be open because the supply voltage VDDY which is lower than the power voltage VDD by a threshold voltage of the second drive element (N20 of FIG. 3) is applied to a source terminal of the PMOS transistor P42 and the node ND41 is driven to a logic “high” level.

The PMOS transistor P43 of the second buffer 412 may be turned on in response to the second high-order address signal YA12<2> having a logic “low” level, and the NMOS transistor N43 may be turned off in response to the second high-order address signal YA12<2> having a logic “low” level to drive a level of the node ND42 (i.e., an output node of the first inverter) to the power voltage VDD. In such a case, a leakage current path of the first inverter of the second buffer 412 may be open because the first level signal LEV<1> having a logic “high” level is applied to a source terminal of the NMOS transistor N43. The PMOS transistor P44 of the second buffer 412 may be turned off because the node ND42 is driven to a logic “high” level, and the NMOS transistor N44 may be turned on to generate the second column selection signal YI<2> having a logic “low” level. In such a case, a leakage current path of the second inverter of the second buffer 412 may be open because the supply voltage VDDY which is lower than the power voltage VDD by a threshold voltage of the second drive element (N20 of FIG. 3) is applied to a source terminal of the PMOS transistor P44 and the node ND42 is driven to a logic “high” level.

The PMOS transistor P45 of the third buffer 413 may be turned on in response to the third high-order address signal YA12<3> having a logic “low” level, and the NMOS transistor N45 may be turned off in response to the third high-order address signal YA12<3> having a logic “low” level to drive a level of the node ND43 (i.e., an output node of the first inverter) to the power voltage VDD. In such a case, a leakage current path of the first inverter of the third buffer 413 may be open because the first level signal LEV<1> having a logic “high” level is applied to a source terminal of the NMOS transistor N45. The PMOS transistor P46 of the third buffer 413 may be turned off because the node ND43 is driven to a logic “high” level, and the NMOS transistor N46 may be turned on to generate the third column selection signal YI<3> having a logic “low” level. In such a case, a leakage current path of the second inverter of the third buffer 413 may be open because the supply voltage VDDY which is lower than the power voltage VDD by a threshold voltage of the second drive element (N20 of FIG. 3) is applied to a source terminal of the PMOS transistor P46 and the node ND43 is driven to a logic “high” level.

The PMOS transistor P47 of the fourth buffer 414 may be turned on in response to the fourth high-order address signal YA12<4> having a logic “low” level, and the NMOS transistor N47 may be turned off in response to the fourth high-order address signal YA12<4> having a logic “low” level to drive a level of the node ND44 (i.e., an output node of the first inverter) to the power voltage VDD. In such a case, a leakage current path of the first inverter of the fourth buffer 414 may be open because the first level signal LEV<1> having a logic “high” level is applied to a source terminal of the NMOS transistor N47. The PMOS transistor P48 of the fourth buffer 414 may be turned off because the node ND44 is driven to a logic “high” level, and the NMOS transistor N48 may be turned on to generate the fourth column selection signal YI<4> having a logic “low” level. In such a case, a leakage current path of the second inverter of the fourth buffer 414 may be open because the supply voltage VDDY which is lower than the power voltage VDD by a threshold voltage of the second drive element (N20 of FIG. 3) is applied to a source terminal of the PMOS transistor P48 and the node ND44 is driven to a logic “high” level.

Hereinafter, an operation of the column decoder as set forth in the above embodiments will be described with reference to FIGS. 2, 3, 4, 5 and 6 in conjunction with an example that the first column selection signal YI<1> is selected in the write mode and an example that the first column selection signal YI<1> is selected in the read mode.

First, the example that the first column selection signal YI<1> is selected in the write mode will be described.

At a point of time “T1”, the control signal generator 10 may generate the control signal YIDRVEN having a logic “low” level because the write pulse signal CASP_WT is inputted in the write mode.

The first drive element P20 of the power supplier 20 may be turned on in response to the control signal YIDRVEN having a logic “low” level to drive a level of the node ND20 to the power voltage VDD. As a result, the supply voltage signal VDDY on the node ND20 may be generated to have a level of the power voltage VDD.

The pre-decoder 30 may decode the first and second high-order column address signals YA<1:2>, the mid-order column address signal YA<3> and the low-order column address signal YA<4> in response to the I/O control signal BYPREP to generate the first high-order address signal YA12<1> having a logic “high” level, the second to fourth high-order address signals YA12<2:4> having a logic “low” level, the first mid-order address signal YA3<1> having a logic “high” level, the second mid-order address signal YA3<2> having a logic “low” level, the first low-order address signal YA4<1> having a logic “high” level, and the second low-order address signal YA4<2> having a logic “low” level.

The first logic unit 410 of the first decoder 41 may receive the first low-order address signal YA4<1> having a logic “high” level and the first mid-order address signal YA3<1> having a logic “high” level to generate the first level signal LEV<1> having a logic “low” level. The first buffer 411 may buffer the first high-order address signal YA12<1> in response to the first level signal LEV<1> having a logic “low” level to generate the first column selection signal YI<1> having a logic “high” level. In such a case, the second to fourth buffers 412, 413 and 414 may generate the second to fourth column selection signals YI<2:4> having a logic “low” level because the second to fourth high-order address signals YA12<2:4> have a logic “low” level. Further, the second to fourth decoders 42, 43 and 44 may disable the fifth to sixteenth column selection signals YI<5:16> because the second to fourth level signals of the second to fourth decoders 42, 43 and 44 are generated to have a logic “high” level.

Subsequently, at a point of time “T2”, the control signal generator 10 may generate the control signal YIDRVEN having a logic “high” level because the burst length end signal BEND is inputted without any pulses of the burst length information signal ICASP.

The first drive element P20 of the power supplier 20 may be turned off in response to the control signal YIDRVEN having a logic “high” level, and the second drive element N20 may drive the node ND20 to have a voltage level which is lower than the power voltage VDD by a threshold voltage of the second drive element N20. That is, the supply voltage VDDY on the node ND20 may be lower than the power voltage VDD.

The pre-decoder 30 does not decode the first and second high-order column address signals YA<1:2>, the mid-order column address signal YA<3> and the low-order column address signal YA<4> because the I/O control signal BYPREP is not inputted.

The first logic unit 410 of the first decoder 41 may receive the first low-order address signal YA4<1> having a logic “low” level and the first mid-order address signal YA3<1> having a logic “low” level to generate the first level signal LEV<1> having a logic “high” level. The first to fourth buffers 411, 412, 413 and 414 of the first decoder 41 may disable the first to fourth column selection signals YI<1:4> because the first level signal LEV<1> has a logic “high” level. In such a case, since the first level signal LEV<1> having a logic “high” level is applied to the source terminals of the NMOS transistors N41, N43, N45 and N47 of the first decoder 41, leakage current paths of the first inverters of the first decoder 41 may be open. Further, the supply voltage signal VDDY having a voltage level which is lower than the power voltage VDD by a threshold voltage of the second drive element N20 may be applied to the source terminals of the PMOS transistors P42, P44, P46 and P48 of the first decoder 41, and gate terminals of the PMOS transistors P42, P44, P46 and P48 may be driven to a level of the power voltage VDD. Thus, leakage current paths of the second inverters of the first decoder 41 may be open. NMOS transistors of the second to fourth decoders 42, 43 and 44 may execute the same operation as the NMOS transistors of the first decoder 41, and PMOS transistors of the second to fourth decoders 42, 43 and 44 may execute the same operation as the PMOS transistors of the first decoder 41. Thus, leakage current paths of the second to fourth decoders 42, 43 and 44 may also be open.

Next, the example that the first column selection signal YI<1> is selected in the read mode will be described.

At a point of time “T3”, the control signal generator 10 may generate the control signal YIDRVEN having a logic “low” level because the read pulse signal CASP_RD is inputted in the read mode.

The first drive element P20 of the power supplier 20 may be turned on in response to the control signal YIDRVEN having a logic “low” level to drive a level of the node ND20 to the power voltage VDD. As a result, the supply voltage signal VDDY on the node ND20 may be generated to have a level of the power voltage VDD.

The pre-decoder 30 may decode the first and second high-order column address signals YA<1:2>, the mid-order column address signal YA<3> and the low-order column address signal YA<4> in response to the I/O control signal BYPREP to generate the first high-order address signal YA12<1> having a logic “high” level, the second to fourth high-order address signals YA12<2:4> having a logic “low” level, the first mid-order address signal YA3<1> having a logic “high” level, the second mid-order address signal YA3<2> having a logic “low” level, the first low-order address signal YA4<1> having a logic “high” level, and the second low-order address signal YA4<2> having a logic “low” level.

The first logic unit 410 of the first decoder 41 may receive the first low-order address signal YA4<1> having a logic “high” level and the first mid-order address signal YA3<1> having a logic “high” level to generate the first level signal LEV<1> having a logic “low” level. The first buffer 411 may buffer the first high-order address signal YA12<1> in response to the first level signal LEV<1> having a logic “low” level to generate the first column selection signal YI<1> having a logic “high” level. In such a case, the second to fourth buffers 412, 413 and 414 may generate the second to fourth column selection signals YI<2:4> having a logic “low” level because the second to fourth high-order address signals YA12<2:4> have a logic “low” level. Further, the second to fourth decoders 42, 43 and 44 may disable the fifth to sixteenth column selection signals YI<5:16> because the second to fourth level signals of the second to fourth decoders 42, 43 and 44 are generated to have a logic “high” level.

Subsequently, at a point of time “T4”, the control signal generator 10 may generate the control signal YIDRVEN having a logic “high” level because the burst length end signal BEND is inputted without any pulses of the burst length information signal ICASP.

The first drive element P20 of the power supplier 20 may be turned off in response to the control signal YIDRVEN having a logic “high” level, and the second drive element N20 may drive the node ND20 to have a voltage level which is lower than the power voltage VDD by a threshold voltage of the second drive element N20. That is, the supply voltage VDDY on the node ND20 may be lower than the power voltage VDD.

The pre-decoder 30 does not decode the first and second high-order column address signals YA<1:2>, the mid-order column address signal YA<3> and the low-order column address signal YA<4> because the I/O control signal BYPREP is not inputted.

The first logic unit 410 of the first decoder 41 may receive the first low-order address signal YA4<1> having a logic “low” level and the first mid-order address signal YA3<1> having a logic “low” level to generate the first level signal LEV<1> having a logic “high” level. The first to fourth buffers 411, 412, 413 and 414 of the first decoder 41 may disable the first to fourth column selection signals YI<1:4> because the first level signal LEV<1> has a logic “high” level. In such a case, since the first level signal LEV<1> having a logic “high” level is applied to the source terminals of the NMOS transistors N41, N43, N45 and N47 of the first decoder 41, leakage current paths of the first inverters of the first decoder 41 may be open. Further, the supply voltage signal VDDY having a voltage level which is lower than the power voltage VDD by a threshold voltage of the second drive element N20 may be applied to the source terminals of the PMOS transistors P42, P44, P46 and P48 of the first decoder 41, and gate terminals of the PMOS transistors P42, P44, P46 and P48 may be driven to a level of the power voltage VDD. Thus, leakage current paths of the second inverters of the first decoder 41 may be open. NMOS transistors of the second to fourth decoders 42, 43 and 44 may execute the same operation as the NMOS transistors of the first decoder 41, and PMOS transistors of the second to fourth decoders 42, 43 and 44 may execute the same operation as the PMOS transistors of the first decoder 41. Thus, leakage current paths of the second to fourth decoders 42, 43 and 44 may also be open.

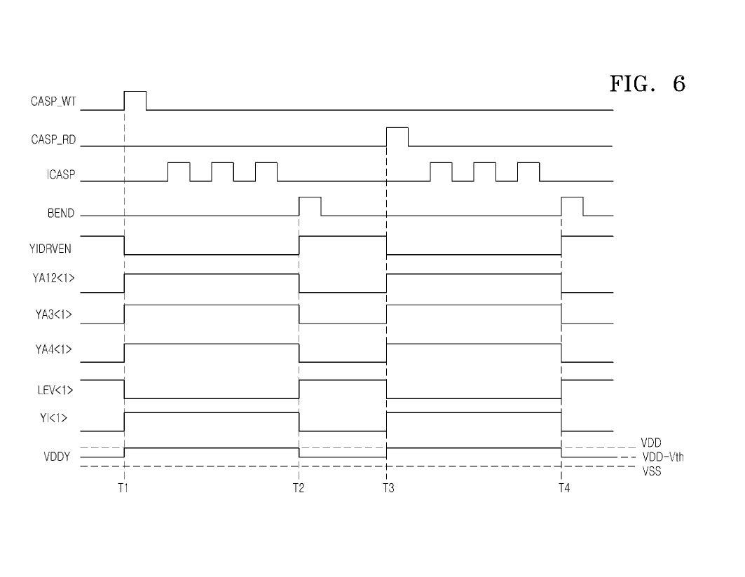

As described above, the column decoder described with reference to FIG. 6 may supply a voltage lower than the power voltage VDD to the source terminals of the PMOS transistors therein and may supply the power voltage VDD to the source terminals of the NMOS transistors therein during operations (e.g., a standby mode) other than the write and read operations. As a result, leakage current paths of the PMOS transistors and the NMOS transistors in the column decoder may be opened to reduce the power consumption of the column decoder.

An operation of the column decoder according to other embodiments of the present invention will be described hereinafter with reference to FIGS. 2, 3, 4, 5 and 7 in conjunction with an example that the first column selection signal YI<1> is continuously selected in the write mode and the read mode without any intervals between the write and read modes.

First, at a point of time “T5”, the control signal generator 10 may generate the control signal YIDRVEN having a logic “low” level because the write pulse signal CASP_WT is inputted in the write mode.

The first drive element P20 of the power supplier 20 may be turned on in response to the control signal YIDRVEN having a logic “low” level to drive a level of the node ND20 to the power voltage VDD. As a result, the supply voltage signal VDDY may be generated to have a level of the power voltage VDD.

The pre-decoder 30 may decode the first and second high-order column address signals YA<1:2>, the mid-order column address signal YA<3> and the low-order column address signal YA<4> in response to the I/O control signal BYPREP to generate the first high-order address signal YA12<1> having a logic “high” level, the second to fourth high-order address signals YA12<2:4> having a logic “low” level, the first mid-order address signal YA3<1> having a logic “high” level, the second mid-order address signal YA3<2> having a logic “low” level, the first low-order address signal YA4<1> having a logic “high” level, and the second low-order address signal YA4<2> having a logic “low” level.

The first logic unit 410 of the first decoder 41 may receive the first low-order address signal YA4<1> having a logic “high” level and the first mid-order address signal YA3<1> having a logic “high” level to generate the first level signal LEV<1> having a logic “low” level. The first buffer 411 may buffer the first high-order address signal YA12<1> in response to the first level signal LEV<1> having a logic “low” level to generate the first column selection signal YI<1> having a logic “high” level. In such a case, the second to fourth buffers 412, 413 and 414 may generate the second to fourth column selection signals YI<2:4> having a logic “low” level because the second to fourth high-order address signals YA12<2:4> have a logic “low” level. Further, the second to fourth decoders 42, 43 and 44 may disable the fifth to sixteenth column selection signals YI<5:16> because the second to fourth level signals of the second to fourth decoders 42, 43 and 44 are generated to have a logic “high” level.

Subsequently, at a point of time “T6”, the control signal generator 10 may generate the control signal YIDRVEN having a logic “low” level because the read pulse signal CASP_RD is inputted in the read mode.

The first drive element P20 of the power supplier 20 may be turned on in response to the control signal YIDRVEN having a logic “low” level to drive a level of the node ND20 to the power voltage VDD. As a result, the supply voltage signal VDDY on the node ND20 may be generated to have a level of the power voltage VDD.

The pre-decoder 30 may decode the first and second high-order column address signals YA<1:2>, the mid-order column address signal YA<3> and the low-order column address signal YA<4> in response to the I/O control signal BYPREP to generate the first high-order address signal YA12<1> having a logic “high” level, the second to fourth high-order address signals YA12<2:4> having a logic “low” level, the first mid-order address signal YA3<1> having a logic “high” level, the second mid-order address signal YA3<2> having a logic “low” level, the first low-order address signal YA4<1> having a logic “high” level, and the second low-order address signal YA4<2> having a logic “low” level.

The first logic unit 410 of the first decoder 41 may receive the first low-order address signal YA4<1> having a logic “high” level and the first mid-order address signal YA3<1> having a logic “high” level to generate the first level signal LEV<1> having a logic “low” level. The first buffer 411 may buffer the first high-order address signal YA12<1> in response to the first level signal LEV<1> having a logic “low” level to generate the first column selection signal YI<1> having a logic “high” level. In such a case, the second to fourth buffers 412, 413 and 414 may generate the second to fourth column selection signals YI<2:4> having a logic “low” level because the second to fourth high-order address signals YA12<2:4> have a logic “low” level. Further, the second to fourth decoders 42, 43 and 44 may disable the fifth to sixteenth column selection signals YI<5:16> because the second to fourth level signals of the second to fourth decoders 42, 43 and 44 are generated to have a logic “high” level.

Subsequently, at a point of time “T7”, the control signal generator 10 may generate the control signal YIDRVEN having a logic “high” level because the burst length end signal BEND is inputted without any pulses of the burst length information signal ICASP.

The first drive element P20 of the power supplier 20 may be turned off in response to the control signal YIDRVEN having a logic “high” level, and the second drive element N20 may drive the node ND20 to have a voltage level which is lower than the power voltage VDD by a threshold voltage of the second drive element N20. That is, the supply voltage VDDY on the node ND20 may be lower than the power voltage VDD.

The pre-decoder 30 does not decode the first and second high-order column address signals YA<1:2>, the mid-order column address signal YA<3> and the low-order column address signal YA<4> because the I/O control signal BYPREP is not inputted.

The first logic unit 410 of the first decoder 41 may receive the first low-order address signal YA4<1> having a logic “low” level and the first mid-order address signal YA3<1> having a logic “low” level to generate the first level signal LEV<1> having a logic “high” level. The first to fourth buffers 411, 412, 413 and 414 of the first decoder 41 may disable the first to fourth column selection signals YI<1:4> because the first level signal LEV<1> has a logic “high” level. In such a case, since the first level signal LEV<1> having a logic “high” level is applied to the source terminals of the NMOS transistors N41, N43, N45 and N47 of the first decoder 41, leakage current paths of the first inverters of the first decoder 41 may be open. Further, the supply voltage signal VDDY having a voltage level which is lower than the power voltage VDD by a threshold voltage of the second drive element N20 may be applied to the source terminals of the PMOS transistors P42, P44, P46 and P48 of the first decoder 41, and gate terminals of the PMOS transistors P42, P44, P46 and P48 may be driven to a level of the power voltage VDD. Thus, leakage current paths of the second inverters of the first decoder 41 may be open. NMOS transistors of the second to fourth decoders 42, 43 and 44 may execute the same operation as the NMOS transistors of the first decoder 41, and PMOS transistors of the second to fourth decoders 42, 43 and 44 may execute the same operation as the PMOS transistors of the first decoder 41. Thus, leakage current paths of the second to fourth decoders 42, 43 and 44 may also be open.

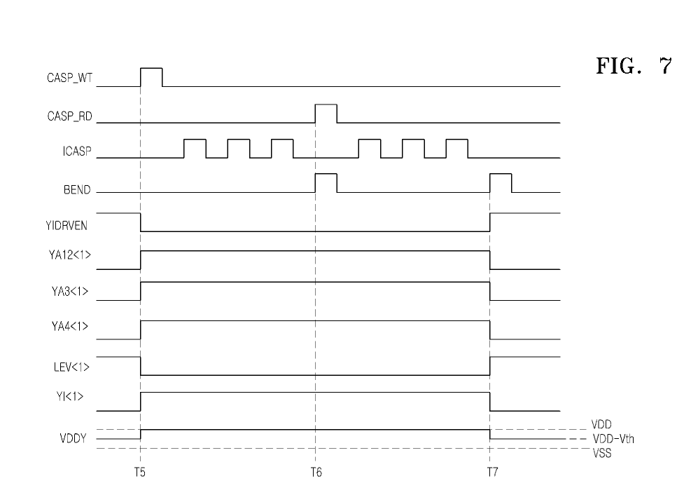

As described above, the column decoder described with reference to FIG. 7 may also supply a voltage lower than the power voltage VDD to the source terminals of the PMOS transistors therein and may supply the power voltage VDD to the source terminals of the NMOS transistors therein during operations (e.g., a standby mode) other than the write and read operations. As a result, leakage current paths of the PMOS transistors and the NMOS transistors in the column decoder may be opened to reduce the power consumption of the column decoder.

The various examples of the embodiments of the present invention have been disclosed above for illustrative purposes. Those skilled in the art will appreciate that various modifications, additions and substitutions are possible, without departing from the scope and spirit of the inventive concept as disclosed in the accompanying claims.

What is claimed is:

1. A column decoder comprising:
a control signal generator configured to generate a control signal enabled from a start point of time of a write mode or a read mode till an end point of time of a burst length;
a power supplier configured to generate a supply voltage signal from a power voltage in response to the control signal, a level of the supply voltage signal being controlled according to the control signal; and
a column selection signal generator configured to operate while the supply voltage signal is supplied thereto,
wherein the column selection signal generator generates one of column selection signals, which is selectively enabled according to a logic combination of a high-order address signal, a mid-order address signal and a low-order address signal which are generated by decoding column address signals.

2. The column decoder of claim 1, wherein the control signal is enabled when a write pulse signal is inputted in the write mode or when a read pulse signal is inputted in the read mode.

3. The column decoder of claim 1, wherein the control signal is disabled when a burst length end signal is inputted at the end point of time of the burst length.

4. The column decoder of claim 1, wherein the column address signals include a high-order column address signal, a mid-order column address signal and a low-order column address signal, and the high-order address signal, the mid-order address signal and the low-order address signal include first and second high-order address signals, first and second mid-order address signals and first and second low-order address signals, the column decoder further comprising:
a pre-decoder configured to decode the high-order column address signal, the mid-order column address signal and the low-order column address signal in response to an input/output control signal to generate the first and second high-order address signals, the first and second mid-order address signals and the first and second low-order address signals.

5. The column decoder of claim 1, wherein the power supplier includes:
a first drive element configured to drive a first node to a level of the power voltage to generate the supply voltage signal on the first node when the control signal is enabled; and
a second drive element configured to drive the first node to a level lower than the power voltage by a predetermined level to generate the supply voltage signal on the first node when the control signal is disabled.

6. The column decoder of claim 4:
wherein the column selection signals include first to eighth column selection signals; and
wherein the column selection signal generator includes:
a first decoder configured to operate with the supply voltage signal and configured to buffer the first and second high-order address signals to generate one of the first and second column selection signals, which is selectively enabled when the first low-order address signal and the first mid-order address signal are enabled;
a second decoder configured to operate with the supply voltage signal and configured to buffer the first and second high-order address signals to generate one of the third and fourth column selection signals, which is selectively enabled when the second low-order address signal and the first mid-order address signal are enabled;
a third decoder configured to operate with the supply voltage signal and configured to buffer the first and second high-order address signals to generate one of the fifth and sixth column selection signals, which is selectively enabled when the first low-order address signal and the second mid-order address signal are enabled; and
a fourth decoder configured to operate with the supply voltage signal and configured to buffer the first and second high-order address signals to generate one of the seventh and eighth column selection signals, which is selectively enabled when the second low-order address signal and the second mid-order address signal are enabled.

7. The column decoder of claim 6, wherein the first decoder includes:
a first logic unit configured to drive a second node to a level of the power voltage to generate a first level signal on the second node when at least one of the first low-order address signal and the first mid-order address signal is disabled;
a first buffer configured to be disposed between a supply voltage terminal and the second node and configured to buffer the first high-order address signal to generate the first column selection signal; and
a second buffer configured to be disposed between the supply voltage terminal and the second node and configured to buffer the second high-order address signal to generate the second column selection signal.

8. The column decoder of claim 6, wherein the second decoder includes:
a second logic unit configured to drive a third node to a level of the power voltage to generate a second level signal on the third node when at least one of the second low-order address signal and the first mid-order address signal is disabled;
a first buffer configured to be disposed between the supply voltage terminal and the second node and configured to buffer the first high-order address signal to generate the third column selection signal; and
a second buffer configured to be disposed between the supply voltage terminal and the second node and configured to buffer the second high-order address signal to generate the fourth column selection signal.

9. The column decoder of claim 6, wherein the third decoder includes:
a third logic unit configured to drive a fourth node to a level of the power voltage to generate a third level signal on the fourth node when at least one of the first low-order address signal and the second mid-order address signal is disabled;
a first buffer configured to be disposed between the supply voltage terminal and the second node and configured to buffer the first high-order address signal to generate the fifth column selection signal; and
a second buffer configured to be disposed between the supply voltage terminal and the second node and configured to buffer the second high-order address signal to generate the sixth column selection signal.

10. The column decoder of claim 6, wherein the fourth decoder includes:
a fourth logic unit configured to drive a fifth node to a level of the power voltage to generate a fourth level signal on the fifth node when at least one of the second low-order address signal and the second mid-order address signal is disabled;
a first buffer configured to be disposed between the supply voltage terminal and the second node and configured to buffer the first high-order address signal to generate the seventh column selection signal; and
a second buffer configured to be disposed between the supply voltage terminal and the second node and configured to buffer the second high-order address signal to generate the eighth column selection signal.

11. A column decoder comprising:
a power supplier configured to generate a supply voltage signal from a power voltage in response to a control signal enabled from a start point of time of a write mode or a read mode till an end point of time of a burst length, a level of the supply voltage signal being controlled according to the control signal; and
a column selection signal generator configured to operate while the supply voltage signal is supplied thereto,
wherein the column selection signal generator generates one of column selection signals, which is selectively enabled according to a logic combination of a high-order address signal, a mid-order address signal and a low-order address signal which are generated by decoding column address signals.

12. The column decoder of claim 11, wherein the supply voltage signal is generated to have a voltage level which is lower than the power voltage by a predetermined level when the control signal is disabled.

13. The column decoder of claim 11, wherein the control signal is enabled when a write pulse signal is inputted in the write mode or when a read pulse signal is inputted in the read mode.

14. The column decoder of claim 13, wherein the control signal is disabled when a burst length end signal is inputted at the end point of time of the burst length.

15. The column decoder of claim 11, wherein the power supplier includes:
a first drive element configured to drive a first node to a level of the power voltage to generate the supply voltage signal on the first node when the control signal is enabled; and
a second drive element configured to drive the first node to a level lower than the power voltage by a predetermined level to generate the supply voltage signal on the first node when the control signal is disabled.

16. The column decoder of claim 12:
wherein the high-order address signal, the mid-order address signal and the low-order address signal include first and second high-order address signals, first and second mid-order address signals and first and second low-order address signals, respectively; and
wherein the column selection signals include first to eighth column selection signals,
wherein the column selection signal generator includes:
a first decoder configured to operate with the supply voltage signal and configured to buffer the first and second high-order address signals to generate one of the first and second column selection signals, which is selectively enabled when the first low-order address signal and the first mid-order address signal are enabled;
a second decoder configured to operate with the supply voltage signal and configured to buffer the first and second high-order address signals to generate one of the third and fourth column selection signals, which is selectively enabled when the second low-order address signal and the first mid-order address signal are enabled;
a third decoder configured to operate with the supply voltage signal and configured to buffer the first and second high-order address signals to generate one of the fifth and sixth column selection signals, which is selectively enabled when the first low-order address signal and the second mid-order address signal are enabled; and
a fourth decoder configured to operate with the supply voltage signal and configured to buffer the first and second high-order address signals to generate one of the seventh and eighth column selection signals, which is selectively enabled when the second low-order address signal and the second mid-order address signal are enabled.

17. A column decoder comprising:
a control signal generator configured to generate a control signal for a period starting from receiving a write pulse or read pulse signal and ending with a burst length signal;
a power supplier configured to generate a supply voltage signal from a power voltage in response to the control signal, a level of the supply voltage signal being controlled according to the control signal; and
a column selection signal generator configured to operate while the supply voltage signal is supplied thereto,
wherein the column selection signal generator generates column selection signals in response to address signals.

18. The column decoder of claim 17, wherein the power supplier includes:
a first drive element configured to drive a first node to a level of the power voltage to generate the supply voltage signal on the first node in response to a control signal; and
a second drive element configured to drive the first node to a level lower than the power voltage by a predetermined level to generate the supply voltage signal on the first node in response to the control signal.

19. The column decoder of claim 18, wherein:
the first drive element is configured for receiving the control signal and is coupled between the power voltage and the first node; and
the second drive element comprises a transistor having a gate and drain electrically coupled to the power voltage, and a source connected to the first node.
